(19) United States
(12) Patent Application Publication
(10) Pub. No.: US 2009/0073776 A1
(43) Pub. Date: Mar. 19, 2009

(54) NONVOLATILE SEMICONDUCTOR MEMORY DEVICE

(75) Inventor: Noriaki KODAMA, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, Kawasaki (JP)

(21) Appl. No.: 12/212,067

(22) Filed: Sep. 17, 2008

(30) Foreign Application Priority Data
Sep. 19, 2007 (JP) 2007-242397

(51) Int. Cl. G11C 16/06; H01L 29/76; G11C 7/00

(52) U.S. Cl. 365/185.29; 257/390; 365/189.07; 365/185.18; 257/E29.226

(57) ABSTRACT

A nonvolatile semiconductor memory device is provided in which stable transistor characteristics with little variation can be obtained, and sufficient threshold voltage and ON current fluctuations can be obtained. A source 2 and a drain 3 formed on a surface of a semiconductor substrate 1, and a gate electrode 5 formed via a gate insulating film 4 on the semiconductor substrate 1 between the source 2 and the drain 3 are provided, and a region of part of the gate electrode 5 forms a non-doped region 10 in which an impurity is not implanted in polysilicon, and another region of the gate electrode 5 forms a doped region 9 in which an impurity is implanted in the polysilicon.

### REFERENCE TO RELATED APPLICATION

This application is based on and claims the benefit of the priority of Japanese patent application No. 2007-242397 filed on Sep. 19, 2007, the disclosure of which is incorporated herein in its entirety by reference thereto.

### FIELD OF THE INVENTION

This invention relates to a nonvolatile semiconductor memory device.

### BACKGROUND OF THE INVENTION

There is an increasing need for small capacity nonvolatile ROM (Read Only Memory) in storage of security codes for LSI (Large Scale Integration) for digital consumer electronics and mobile telephones, and trimming of color adjustment parameters for LCD (Liquid Crystal Display) drivers, temperature parameters for TCXOs (Temperature Compensated Crystal Oscillator) and the like. In such nonvolatile ROM, a separate chip such as an EEPROM (Electronically Erasable and Programmable Read Only Memory) is often installed in a SIP (System In Package). However, recently a floating gate memory that can be formed in a standard CMOS (Complementary Metal Oxide Semiconductor) process without additional processing has been proposed (for example, Patent Document 1 or the like), and this type of floating gate memory is being installed in nonvolatile ROM.

However, as nonvolatile ROM formed in a standard CMOS process without additional processing, being adapted also to a thin gate insulating film process, a memory type has been proposed in which, for example, a conduction state of a MOS transistor is controlled, and a conduction resistance value thereof is deteriorated to perform writing (refer to Patent Document 2). In a nonvolatile memory in which a floating gate is formed between a gate and a substrate as described in Patent Document 2, the floating gate is a charge accumulating region. Thus, in cases in which the gate insulating film is thin, deterioration of charge retention characteristic is actualized, charge loss bits cannot be ignored, and usage may no longer be possible as regards reliability.

Furthermore, as nonvolatile ROM formed in a standard CMOS process without additional processing, being adapted also to a thin gate insulating film process, a nonvolatile memory type has been proposed in which electrons are trapped in a lower part of a side spacer, to perform writing (refer to Patent Document 3). According to this nonvolatile memory, it is possible to arrange such that, without changing normal CMOS manufacturing processes at all, no effect of gate oxidation film thickness is received.

Furthermore, as a type similar to nonvolatile memory of Patent Document 3, as in FIG. 7, there is a memory cell structure in which a source 102 and a drain 103 formed from an N+ diffusion layer in a surface of a semiconductor substrate 101 are formed, in a channel therebetween a gate electrode 105 is formed via a gate insulating film 104, sidewalls 106a and 106b are formed on both sides of the gate electrode 105, an extension 107 is formed, being a low density region (N− diffusion layer) below the sidewall 106a on the source 102 side in the semiconductor substrate 101 between the gate electrode 105 and the source 102 (the drain 103 is also possible), and an extension is not formed below the side wall 106b on the drain 103 side. An operation of writing to the memory cell structure includes, for example, applying a positive voltage less than or equal to a junction withstanding voltage to the drain 103 on a side at which an extension is not formed, injecting/trapping an avalanche hot hole in a charge accumulating region 108 in a lower part of the sidewall 106b on the drain 103 side, and lowering a threshold by a trap hole trapped in the sidewall 106b.

### [Patent Document 1]

JP Patent Kokai Publication No. JP-P2005-533372A

### [Patent Document 2]

JP Patent Kokai Publication No. JP-P2005-353106A

### [Patent Document 3]

JP Patent Kokai Publication No. JP-P2006-191122A

### SUMMARY OF THE DISCLOSURE

The entire disclosures of the above documents are incorporated herein by references thereto. The following analyses are given by the present invention.

However, in the memory cell structure of FIG. 7, there is a problem in that variations in transistor characteristics related to initial threshold voltage Vt and ON current Ion are large, and also that fluctuations of the threshold voltage Vt and the ON current Ion due to writing are small and furthermore that variations are large. That is, if an offset structure without an extension to one of source and drain is used, parasitic resistance of the offset region becomes large, but effects of variations in extension surface state, sidewall length, sidewall shape, and the like, are reflected to a large extent in the transistor characteristics, and variations in the transistor characteristics become large.

Furthermore, in the memory cell structure of FIG. 7, since a boundary face of the semiconductor substrate and a sidewall in a state in which surface layer damage has occurred in etching of the gate electrode, is a charge accumulating region, variation in charge trapping efficiency is large, and variation in a writing characteristic easily occurs.

Furthermore, in the memory cell structure of FIG. 7, as the offset structure without an extension to one of the source and drain, since a junction is formed only at a high density diffusion layer, deterioration of withstanding voltage occurs, and when performing writing by hot carrier generation, a problem occurs in that a sufficiently high voltage cannot be applied, and sufficient threshold voltage Vt and ON current Ion fluctuations cannot be obtained.

It is a main object of the present invention to provide a nonvolatile semiconductor memory device in which stable transistor characteristics with little variation can be obtained, and sufficient threshold voltage and ON current fluctuations can be obtained.

In one aspect of the present invention, there is provided a nonvolatile semiconductor memory device comprising a source and a drain formed on a semiconductor substrate surface, and a gate electrode formed via a gate insulating film on the semiconductor substrate between the source and the drain, wherein a region of part of the gate electrode forms a non-doped region, (e.g., in which an impurity is not implanted in polysilicon), and another region of the gate electrode forms a doped region (e.g., in which an impurity is implanted in the polysilicon).

The meritorious effects of the present invention are summarized as follows.

According to the present invention, there is an effect in that stable transistor characteristics with little variation can be obtained, and also, in order to generate a hot carrier when performing a writing operation, sufficient voltage can be applied and sufficient threshold voltage Vt and ON current Ion fluctuations can be obtained. Since a charge accumulating region in which the hot carrier in the writing operation is trapped is near a boundary face of an electrode and a gate insulating film, and is a stable boundary face region, not a region in which a semiconductor surface is struck in etching, stable characteristics with little variation are obtained.

### BRIEF DESCRIPTIONS OF THE DRAWINGS

FIG. 1 is a partial sectional view schematically showing a configuration of a nonvolatile semiconductor memory device according to a first exemplary embodiment of the invention.

FIG. 2 is a partial sectional view schematically showing a configuration of the nonvolatile semiconductor memory device according to a second exemplary embodiment of the invention.

FIG. 3 is a partial sectional view schematically showing a configuration of the nonvolatile semiconductor memory device according to a third exemplary embodiment of the invention.

FIG. 4 is a circuit diagram schematically showing a configuration of a memory cell in the semiconductor memory device according to a fourth exemplary embodiment of the invention.

FIG. 5 is a list showing operating voltage conditions of a memory cell in the semiconductor memory device according to the first exemplary embodiment of the present invention.

FIG. 6 is a circuit diagram schematically showing an internal circuit of the semiconductor memory device according to a fifth exemplary embodiment of the invention.

FIG. 7 is a partial sectional view schematically showing a configuration of a nonvolatile semiconductor memory device according to a related art.

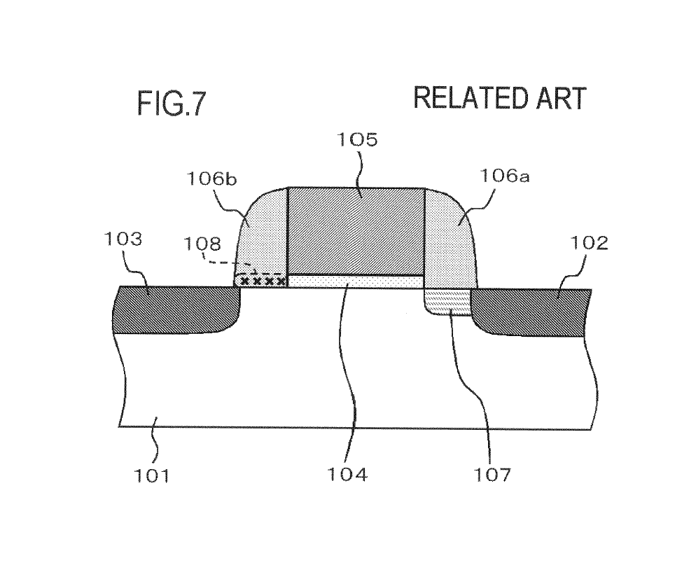

### PREFERRED MODES OF THE INVENTION

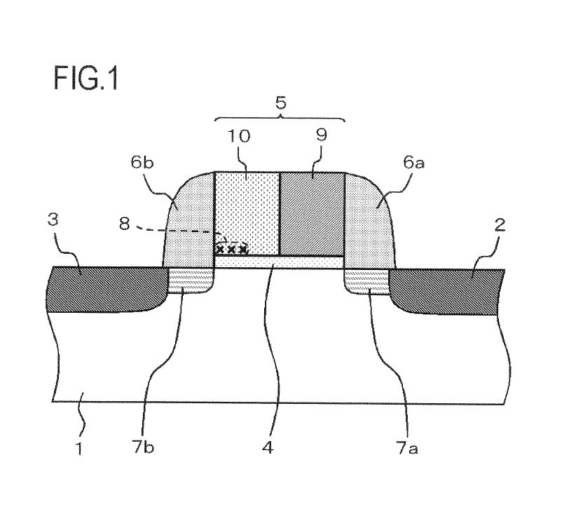

A nonvolatile semiconductor memory device according to an exemplary embodiment of the present invention is provided with a source (2 in FIG. 1) and a drain (3 in FIG. 1) formed on a semiconductor substrate (1 in FIG. 1) surface, and a gate electrode (5 in FIG. 1) formed via a gate insulating film (4 in FIG. 1) on the semiconductor substrate (1 in FIG. 1) between the source (2 in FIG. 1) and the drain (3 in FIG. 1), wherein a region of part of the gate electrode (5 in FIG. 1) forms a non-doped region (10 in FIG. 1) in which an impurity is not implanted in polysilicon, and another region of the gate electrode (5 in FIG. 1) forms a doped region (9 in FIG. 1) in which an impurity is implanted in the polysilicon.

The non-doped region may be arranged at a prescribed portion on the source side or the drain side within the gate electrode. The doped region may be arranged at a prescribed portion on the source side or the drain side within the gate electrode, and the non-doped region is arranged in a central portion of the gate electrode. Part of the non-doped region may be configured as a charge accumulating region.

The charge accumulating region may be a prescribed portion near a boundary face with the gate insulating film in the non-doped region.

The gate electrode may have a silicide layer on a (e.g., polysilicon) layer formed of the doped region and the non-doped region.

The gate electrode may have a metal layer on the silicide layer. The gate electrode may have a metal layer on a (e.g., polysilicon) layer formed of the doped region and the non-doped region.

A writing operation may be performed by applying a positive voltage to the gate electrode and the drain, and trapping a charge in a part of the non-doped region.

A writing operation may be performed by applying a positive voltage to the gate electrode and the source.

An erasing operation may be performed by applying a positive voltage to the drain and applying a negative voltage to the gate electrode, to release charge from the non-doped region.

The gate electrode may be applied to a gate electrode of a driver transistor or a load transistor in an SRAM cell.

The gate electrode may be applied to a gate electrode of a transistor in a main cell and a reference cell, and a comparison circuit may be provided which judges data based on voltage from a prescribed cell of the main cell and a voltage from the reference cell.

The non-doped region may comprise a region in which an impurity is not implanted in polysilicon, and the doped region may comprise a region in which an impurity is implanted in polysilicon, The non-doped region may act as a charge accumulating region.

### First Exemplary Embodiment

A description is given using the drawings concerning the nonvolatile semiconductor memory device according to a first exemplary embodiment of the present invention. FIG. 1 is a partial sectional view schematically showing a configuration of the nonvolatile semiconductor memory device according to the first exemplary embodiment of the invention.

The nonvolatile semiconductor memory device of FIG. 1 is an N-channel type, N+ type source 2 and drain 3 are formed on a surface of a P-type semiconductor substrate 1 (P-well is also possible), and a gate electrode 5 is formed via a gate insulating film 4 (for example, silicon oxide film) on the semiconductor substrate 1 between the source 2 and the drain 3. A region of part of the gate electrode 5 is a non-doped region 10 (polysilicon), and another region of the gate electrode 5 is a doped region 9 (N+ polysilicon). In FIG. 1, a portion on the drain 3 side of the gate electrode 5 is the non-doped region 10, and a portion on the source 2 side of the gate electrode 5 is the doped region 9. Sidewalls 6a and 6b (for example, silicon oxide film) are formed on both sides of the gate electrode 5, and N-type extensions 7a and 7b are formed in the semiconductor substrate 1 below the sidewalls 6a and 6b.

In the above description, the nonvolatile semiconductor memory device was described with an N-channel type as an example, but in cases of P-channel types, each polarity of the semiconductor substrate 1, the source 2, the drain 3, the extensions 7a and 7b, and the doped region 9 of the gate electrode 5 are reversed.

The nonvolatile semiconductor memory device of FIG. 1 can be formed in a standard CMOS process without additional processing. First, the gate insulating film 4 is formed on the semiconductor substrate 1; after that, the gate electrode 5 formed from polysilicon is formed on the gate insulating film 4; a mask is formed only in a prescribed region on the gate electrode 5; and the gate insulating film 4 and the gate electrode 5 in regions outside of the mask are removed by etching. Next, leaving the mask on the gate electrode 5, the N-type extensions 7a and 7b are formed by implanting an impurity into the semiconductor substrate 1, and the mask is removed. Next, the sidewalls 6a and 6b are formed on both sides of the gate electrode 5. Next, after forming the mask on the non-doped region 10 of the gate electrode 5, the P+ type source 2 and drain 3 are formed by implanting an impurity into the semiconductor substrate 1 (a region into which an impurity is implanted similar to the extensions 7a and 7b). Here, when the source 2 and drain 3 are formed, the doped region 9 of the gate electrode 5 has the impurity implanted and is a P+ type, and the impurity is not implanted into the non-doped region 10 of the gate electrode 5 that is masked. According to the above, a nonvolatile semiconductor memory device that is similar to FIG. 1 is possible.

Next, a description will be given of one example of operation of the nonvolatile semiconductor memory device according to the first exemplary embodiment of the present invention.

In a writing operation, in a state (state “0”) in which a hot carrier is not trapped in a lower portion of the non-doped region 10 of the gate electrode 5, a positive voltage (for example, 3V) lower than a junction withstanding voltage is applied to the drain 3, a positive voltage (for example, 4.5V) is applied to the gate electrode 5, and a hot carrier is injected into a lower portion of the non-doped region 10 of the gate electrode 5. The semiconductor substrate 1 and the source 2 are at 0V. Thus, by the hot carrier being trapped near a boundary face with the gate insulating film 4 in the non-doped region 10, “1” is written, and fluctuations in the threshold voltage Vt and the ON current Ion of a transistor occur.

In a reading operation, a positive voltage (for example, 1.8V) is applied to the source 2, and a positive voltage (for example, 1.8V) is applied to the gate electrode 5. The semiconductor substrate 1 and the drain 3 are at 0V. At this time, in a state (state “1”) in which the carrier is trapped in the non-doped region 10, a current flows from the drain 3 to the source 2, and in a state (state “0”) in which the carrier is not trapped in the non-doped region 10 a current does not flow from the drain 3 to the source 2. By judging whether or not a current is flowing from the drain 3 to the source 2, reading is performed.

In an erasing operation, in a state (state “1”) in which the hot carrier is trapped in a lower portion of the non-doped region 10 of the gate electrode 5, a positive voltage (for example, 3V) is applied to the drain 3, a negative voltage (for example, −2V) is applied to the gate electrode 5, and the hot carrier is ejected from the non-doped region 10. The semiconductor substrate 1 is at 0V, and the drain 3 is open.

According to the first exemplary embodiment, there is an effect in that stable transistor characteristics with little variation can be obtained, and also, in generating a hot carrier when performing the writing operation, sufficient voltage can be applied and sufficient threshold voltage Vt and ON current Ion fluctuations can be obtained. Since a charge accumulating region, in which the hot carrier in the writing operation is trapped, is near a boundary face of the gate insulating film 4 and the gate electrode 5, and is a stable boundary face region, not a region in which a semiconductor surface is struck in etching, stable characteristics with little variation are obtained.

Furthermore, according to the first exemplary embodiment, since formation of the source 2 and drain 3 forming diffusion layers and the extensions 7a and 7b forming LDD regions is the same as in a normal transistor, junction withstanding voltage does not decrease, and there is an effect in that a sufficient voltage can be applied in order to generate the hot carrier when performing a writing operation.

Moreover, according to the first exemplary embodiment, in an LSI product manufactured by a standard CMOS process, with no additional processing, formation is possible by curtailing manufacturing cost, and since adaptation is possible even in a process formed with only a thin gate insulating film, application is possible to low voltage process products.

### Second Exemplary Embodiment

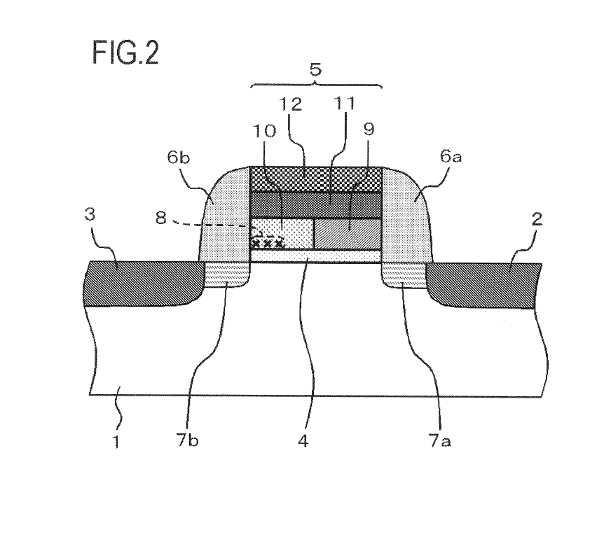

A description will be given using the drawings concerning the nonvolatile semiconductor memory device according to a second exemplary embodiment of the present invention, FIG. 2 is a partial sectional view schematically showing a configuration of the nonvolatile semiconductor memory device according to the second exemplary embodiment of the invention.

In the nonvolatile semiconductor memory device of the second exemplary embodiment, configuration of a gate electrode 5 is different from the first exemplary embodiment. The gate electrode 5 is formed by being built up (stacked) in laminated layers, in order, from a gate insulating film 4 side, of a polysilicon layer in which a doped region 9 (N+ polysilicon) and a non-doped region 10 (polysilicon) are in parallel, a silicide layer 11, and a metal layer 12. A portion on a drain 3 side of the polysilicon layer is the non-doped region 10, and a portion on a source 2 side of the polysilicon layer is the doped region 9. The gate electrode 5 may also be formed by being built up in layers of only the polysilicon layer having the doped region 9 and the non-doped region 10, and the silicide layer, without the metal layer 12. Configuration and operation are otherwise the same as the first exemplary embodiment.

In a method of manufacturing the nonvolatile semiconductor memory device of the second exemplary embodiment, first the gate insulating film 4 is formed on the semiconductor substrate 1, and after that, the polysilicon layer is formed as a film on the gate insulating film. Next, after forming a mask at least on the nondoped region 10 of the polysilicon layer, an impurity is implanted in at least the doped region 9 of the polysilicon layer, and the mask is removed. Next, the silicide layer 11 and the metal layer 12 are layered, in that order, on the polysilicon layer; a mask is formed only on a prescribed region on the metal layer 12; the gate insulating film 4, the doped region 9, the non-doped region 10, the silicide layer 11, and the metal layer 12 region outside of the mask are removed by etching, and the mask is removed. Next, by implanting an impurity into the semiconductor substrate 1, N− type extensions 7a and 7b are formed. Next, sidewalls 6a and 6b are formed on the two sides of the gate electrode 5. Next, by implanting an impurity into the semiconductor substrate 1 (a region into which the impurity is implanted, similar to the extensions 7a and 7b), the P+ type source 2 and drain 3 are formed. According to the above description, a nonvolatile semiconductor memory device that is similar to FIG. 2 is possible.

According to the second exemplary embodiment, an effect similar to the first exemplary embodiment is obtained, and also since the gate electrode 5 has the silicide layer 11 and the metal layer 12 on the polysilicon layer in which the doped region 9 and the non-doped region 10 are in parallel, it is possible to apply a gate voltage also to an offset region between the source 2 and drain 3, and channel via the non-doped region 10. As a result, there is an advantage in that it is possible to reduce channel resistance when reading, and to improve reading current.

### Third Exemplary Embodiment

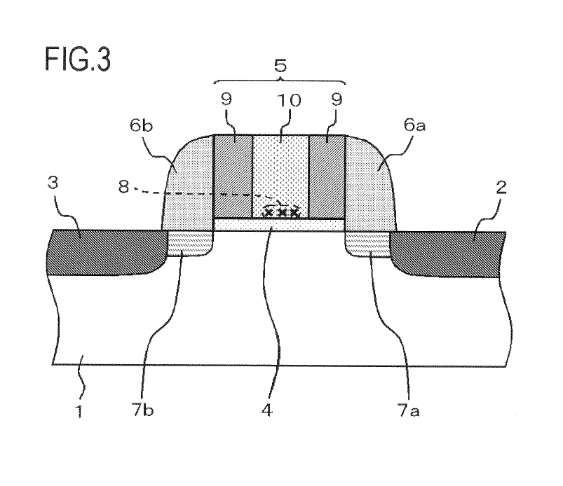

A description will be given using the drawings concerning the nonvolatile semiconductor memory device according to a third exemplary embodiment of the present invention. FIG. 3 is a partial sectional view schematically showing a configuration of the nonvolatile semiconductor memory device according to the third exemplary embodiment of the invention.

In the nonvolatile semiconductor memory device of the third exemplary embodiment, configuration of a gate electrode 5 is different from the first exemplary embodiment. Portions on a drain 3 side and a source 2 side of the gate electrode 5 are doped regions 9 (N+ polysilicon), and a central portion of the gate electrode 5 is a non-doped region 10 (polysilicon) Configuration and operation are otherwise the same as the first exemplary embodiment. Furthermore, a configuration of the gate electrode 5 as in the third exemplary embodiment may be applied to the polysilicon layer of the second exemplary embodiment (layers 9 and 10 of FIG. 2).

According to the third exemplary embodiment, an effect similar to the first exemplary embodiment is obtained.

### Fourth Exemplary Embodiment

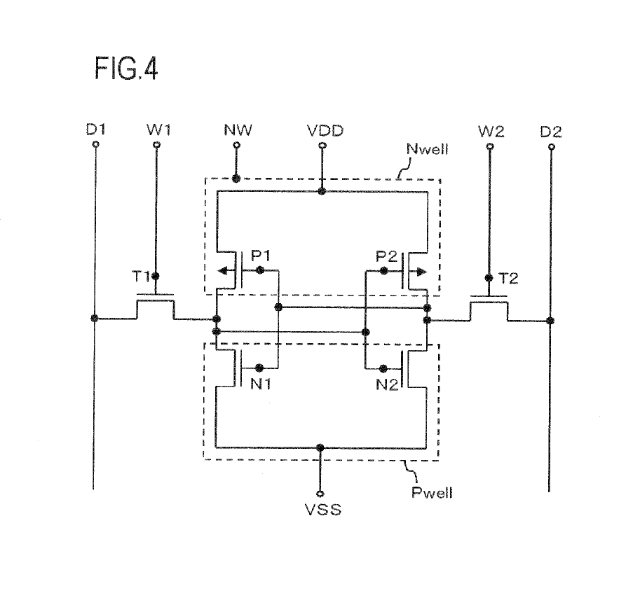

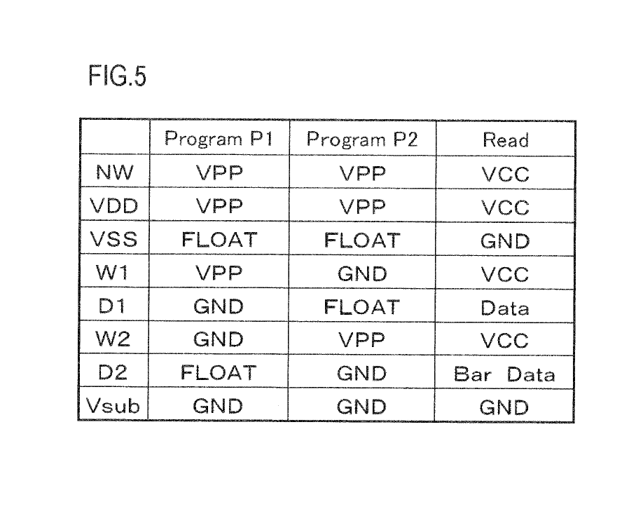

A description will be given using the drawings concerning the nonvolatile semiconductor memory device according to a fourth exemplary embodiment of the present invention. FIG. 4 is a circuit diagram schematically showing a configuration of a memory cell in a nonvolatile semiconductor memory device according to the fourth exemplary embodiment of the invention. FIG. 5 is a list showing operating voltage conditions of the memory cell in the nonvolatile semiconductor memory device according to the first exemplary embodiment of the present invention.

The nonvolatile semiconductor memory device of the fourth exemplary embodiment has a SRAM (Static Random Access Memory) cell that does not need an operation (a refresh operation) for holding stored data (refer to FIG. 4). The SRAM cell has PMOS transistors P1 and P2, NMOS transistors N1 and N2, and transfer MOS transistors T1 and T2. Any gate electrode of the first to the third exemplary embodiment 2 (refer to FIG. 1 to FIG. 3) is applied to gate electrodes of the transistors P1, P2, N1, and N2 that form load transistors or driver transistors of the SRAM cell.

P1 and P2 are formed within an N-type well electrically connected to N-type well wiring NW, and a form flip-flop. A gate of P1 is electrically connected to a gate of N1, a drain of P2, a source of N2, and a drain of T2. A source of P1 is electrically connected to first power supply wiring VDD. A drain of P1 is electrically connected to a source of N1, a gate of P2, a gate of N2, and a drain of T1. A gate of P2 is electrically connected to the gate of N2, the drain of P1, the source of N1, and the drain of T1. A source of P2 is electrically connected to the first power supply wiring VDD. The drain of P2 is electrically connected to the source of N2, the gate of P1, the gate of N1, and the drain of T2.

N1 and N2 are formed within a P-type well. The gate of N1 is electrically connected to the gate of P1, the drain of P2, the source of N2, and the drain of T2. The source of N1 is electrically connected to the drain of P1, the gate of P2, the gate of N2, and the drain of T1. A drain of N1 is electrically connected to second power supply wiring VSS. The gate of N2 is electrically connected to the gate of P2, the drain of P1, the source of N1, and the drain of T1. The source of N2 is electrically connected to the drain of P2, the gate of P1, the gate of N1, and the drain of T2. A drain of N2 is electrically connected to the second power supply wiring VSS.

T1 and T2 are selection transistors for selecting a first memory node formed from P1 and N1, or a second memory node formed from P2 and N2. A gate of T1 is electrically connected to a first word line W1. A source of T1 is electrically connected to a first data line D1. The drain of T1 is electrically connected to the drain of P1, the source of N1, the gate of P2, and the gate of N2. A gate of 12 is electrically connected to a second word line W2. A source of T2 is electrically connected to a second data line D2. The drain of T2 is electrically connected to the gate of P1, the gate of N1, the drain of P2, and the source of N2.

Although not shown in the drawings, there is a driving circuit that is a peripheral circuit in a peripheral region of the SRAM cell. The driving circuit controls voltage applied to the first data line D1, the second data line D2, the first word line W1, the second word line W2, the first power supply wiring VDD, the second power supply wiring VSS, the N-type well wiring NW, and substrate wiring Vsub. Voltage control of the driving circuit will be described later.

Next, a description will be given of operation of the nonvolatile semiconductor memory device according to the fourth exemplary embodiment of the present invention.

When data is written to P1, the driving circuit applies a write voltage VPP that is a positive voltage whose absolute value is lower than a junction withstanding voltage, to the N-type well wiring NW and the first power supply wiring VDD, with the second power supply wiring VSS being floated (Float, open)), applies the positive voltage VPP to the first word wiring W1, applies a ground potential GND to the first data line D1, applies the ground potential GND to the second word line W2, with the second data line D2 being floated (Float, open), and applies the ground potential GND to the substrate wiring Vsub. In this way, the write voltage VPP is applied to the source of P1 and the N-type well, T1 is ON, and the ground potential GND is applied to the drain of P1. In this way, when electrons flow from the source of P1 to the drain of P1, some electrons are trapped in a non-doped region (equivalent to 10 in FIG. 1 to FIG. 3) of the gate electrode of P1. In this way, a state in which data are written to P1 exists.

When data is written to P2, the driving circuit applies the write voltage VPP that is a positive voltage whose absolute value is lower than a junction withstanding voltage, to the N-type well wiring NW and the first power supply wiring VDD, with the second power supply wiring VSS being floated (Float, open), applies the ground potential GND to the first word wiring W1, with the first data line D1 being floated (Float, open), applies the positive voltage VPP to the second word line W2, applies the ground potential GND to the second data line D2, and applies the ground potential GND to the substrate wiring Vsub (refer to FIG. 4 and FIG. 5) In this way, the write voltage VPP is applied to the source of P2 and the N-type well, T2 is ON, and the ground potential GND is applied to the drain of P2. In this way, similar to cases of P1, when electrons flow from the source of P2 to the drain of P2, some electrons are trapped in a non-doped region (equivalent to 10 in FIG. 1 to FIG. 3) of the gate electrode of P2. In this way, a state in which data are written to P2 exists.

In cases in which data of the SRAM cell are read, the driving circuit applies a positive power supply voltage VCC to the N-type well wiring NW and the first power supply wiring VDD, applies the ground potential GND to the second power supply wiring VSS, applies the positive power supply voltage VCC to the first word line W1, applies the positive power supply voltage VCC to the second word line W2, and applies the ground potential GND to the substrate wiring Vsub (refer to FIG. 4 and FIG. 5). In this way, the power supply voltage VCC is applied to the N-type well, the source of P1, and the source of P2, and with T1 and T2 ON, latching is fixed, potential states (Data) of the drain or P1 and the source of N1 are outputted to the first data line D1 via T1, potential states (Bar Data) of the drain of P2 and the source of N2 are outputted to the second data line D2 via T2, and data of the SRAM cell is read.

According to the fourth exemplary embodiment, an effect similar to the first exemplary embodiment is obtained, and since a negative voltage is not used in a writing operation, the peripheral circuit is simplified. Furthermore, since writing is performed by a principle of drain avalanche hot electron injection to P1 and P2, injection efficiency can be made high and writing time made faster.

### Fifth Exemplary Embodiment

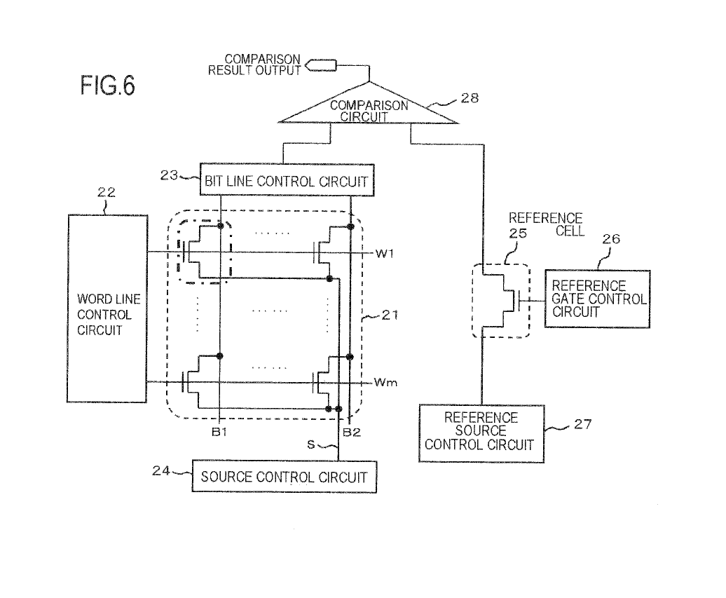

A description will be given using the drawings concerning the nonvolatile semiconductor memory device according to a fifth exemplary embodiment of the present invention. FIG. 6 is a circuit diagram schematically showing an internal circuit of a semiconductor memory device according to the fifth exemplary embodiment of the invention.

The nonvolatile semiconductor memory device has a main cell 21, a word line control circuit 22, a bit line control circuit 23, a source control circuit 24, a reference cell 25, a reference gate control circuit 26, a reference source control circuit 27, and a comparison circuit 28.

The main cell 21 is a cell arranged on a matrix of m rows (X coordinate) and n columns (Y coordinate) of transistors (memory cells) of any of the first to the third exemplary embodiments. A gate electrode of each transistor arranged in a row direction in the main cell 21 is electrically connected to the word line control circuit 22 via common word lines W1 to Wm for each row, A drain of each transistor arranged in a column direction in the main cell 21 is electrically connected to the bit line control circuit 23 via common bit lines B1 to Bn for each column. Sources of all transistors in the main cell 21 are electrically connected to the source control circuit 24 via a source line S.

The word line control circuit 22 is a circuit that selects the word lines W1 to Wm indicated by an address signal, to control voltage of the selected word lines W1 to Wm.

The bit line control circuit 23 is a circuit that selects the bit lines B1 to Bn indicated by an address signal, and outputs voltage of the selected bit lines B1 to Bn towards the comparison circuit 28. The bit line control circuit 23 can also select the bit lines B1 to Bn indicated by an address signal, to control voltage of the selected bit lines B1 to Bn.

The source control circuit 24 is a circuit that controls voltage of the source line S connected to sources of all the transistors in the main cell 21.

The reference cell 25 is a cell in which one of any transistor (memory cell) of the first to the third exemplary embodiments is arranged. A gate electrode of the transistor in the reference cell 25 is electrically connected to the reference gate control circuit 26. A source of the transistor in the reference cell 25 is electrically connected to the reference source control circuit 27. A drain of the transistor in the reference cell 25 is electrically connected to the comparison circuit 28.

The reference gate control circuit 26 is a circuit that controls voltage of the gate electrode of the transistor in the reference cell 25.

The reference source control circuit 27 is a circuit that controls voltage of the source of the transistor in the reference cell 25.

The comparison circuit 28 is a circuit that compares voltage from the bit line control circuit 23 and voltage from the reference cell 25, performs a 0/1 judgment, and outputs a 0/1 comparison result. In the 0/1 judgment of the comparison circuit 28, for example, in cases in which the voltage from the bit line control circuit 23 is larger than the voltage from the reference cell 25, a judgment of 1 may be made, and in cases in which the voltage from the bit line control circuit 23 is less than or equal to the voltage from the reference cell 25, a judgment of 0 may be made.

Next, a description will be given of operation of the nonvolatile semiconductor memory device according to the fifth exemplary embodiment of the present invention.

In a writing operation of a cell surrounded by a thick dashed-doted line in the main cell 21, in a state in which charge is not stored in a non-doped region (equivalent to 10 in FIG. 1 to FIG. 3) of a gate electrode of the cell, the bit line control circuit 23 applies a positive voltage to the bit line B1, the word line control circuit 22 applies a positive voltage to the word line W1, and a hot carrier is injected into the non-doped region (10 in FIG. 1 to FIG. 3) of the gate electrode.

Describing cases in which an address signal to the word line control circuit 22 and the bit line control circuit 23 is “1”, in a reading operation, with regard to the cell surrounded by the thick dashed-dotted line in the main cell 21, in a state in which electrons are stored in the non-doped region (equivalent to 10 in FIG. 1 to FIG. 3) of the gate electrode, the word line control circuit 22 applies a positive voltage to the word line W1, the bit line control circuit 23 selects the bit line B1, and the source control circuit 24 applies a positive voltage, so that a current from the source control circuit 24 is inputted to the comparison circuit 28 via the cell surrounded by the thick dashed-dotted line, the bit line B1, and the bit line control circuit 23. On the other hand, in the reference cell 25, by the reference gate control circuit 26 and the reference source control circuit 27 applying a positive voltage, a current from the reference source control circuit 27 is inputted to the comparison circuit 28 via the reference cell 25. The comparison circuit 28 compares voltage from the bit line control circuit 23 and voltage from the reference cell 25, performs a 0/1 judgment, and outputs a 0/1 comparison result.

In an erasing operation of the cell surrounded by the thick dashed-dotted line in the main cell 21, in a state in which charge is stored in a non-doped region (equivalent to 10 in FIG. 1 to FIG. 3) of the gate electrode of the cell, the bit line control circuit 23 applies a positive voltage to the bit line B1, the word line control circuit 22 applies a negative voltage to the word line W1, and charge is released from the non-doped region (equivalent to 10 in FIG. 1 to FIG. 3).

According to the fifth exemplary embodiment, an effect similar to the first exemplary embodiment is obtained.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A nonvolatile semiconductor memory device comprising:
a source and a drain formed on a semiconductor substrate surface; and
a gate electrode formed via a gate insulating film on said semiconductor substrate between said source and said drain; wherein
a region of part of said gate electrode forms a non-doped region and another region of said gate electrode forms a doped region.

2. The nonvolatile semiconductor memory device according to claim 1, wherein
said non-doped region is arranged at a prescribed portion on said source side or said drain side within said gate electrode.

3. The nonvolatile semiconductor memory device according to claim 1, wherein
said doped region is arranged at a prescribed portion on said source side or said drain side within said gate electrode, and
said non-doped region is arranged in a central portion of said gate electrode.

4. The nonvolatile semiconductor memory device according to claim 1, wherein
part of said non-doped region is configured as a charge accumulating region.

5. The nonvolatile semiconductor memory device according to claim 4, wherein
said charge accumulating region is a prescribed portion near a boundary face with said gate insulating film in said non-doped region.

6. The nonvolatile semiconductor memory device according to claim 1, wherein
said gate electrode has a silicide layer on a layer formed of said doped region and said non-doped region.

7. The nonvolatile semiconductor memory device according to claim 6, wherein
said gate electrode has a metal layer on said silicide layer.

8. The nonvolatile semiconductor memory device according to claim 1, wherein
said gate electrode has a metal layer on a layer formed of said doped region and said non-doped region.

9. The nonvolatile semiconductor memory device according to claim 1, wherein
a writing operation is performed by applying a positive voltage to said gate electrode and said drain, and trapping a charge in a part of said non-doped region.

10. The nonvolatile semiconductor memory device according to claim 1, wherein
a writing operation is performed by applying a positive voltage to said gate electrode and said source.

11. The nonvolatile semiconductor memory device according to claim 1, wherein
an erasing operation is performed by applying a positive voltage to said drain and applying a negative voltage to said gate electrode, to release charge from said non-doped region.

12. The nonvolatile semiconductor memory device according to claim 1, wherein
said gate electrode is applied to a gate electrode of a driver transistor or a load transistor in an SRAM cell.

13. The nonvolatile semiconductor memory device according to claim 1, wherein
said gate electrode is applied to a gate electrode of a transistor in a main cell and a reference cell, and
a comparison circuit is provided which judges data based on voltage from a prescribed cell of said main cell and a voltage from said reference cell.

14. The nonvolatile semiconductor memory device according to claim 1, wherein
said non-doped region comprises a region in which an impurity is not implanted in polysilicon, and said doped region comprises a region in which an impurity is implanted in polysilicon.

15. The nonvolatile semiconductor memory device according to claim 1, wherein
said non-doped region acts as a charge accumulating region.
